(19) United States
(12) Patent Application Publication
(10) Pub. No.: US 2024/0106416 A1
(43) Pub. Date: Mar. 28, 2024

(54) SETTING METHOD OF FILTER COEFFICIENTS AND RELATED FILTER DEVICE

(71) Applicant: Safwan AREKAT, Barbar (BH)

(72) Inventor: Safwan AREKAT, Barbar (BH)

(21) Appl. No.: 18/038,421

(22) PCT Filed: Nov. 25, 2020
(86) PCT No.: PCT/IB2020/061125

§ 371 Date: May 23, 2023

(51) Int. Cl. H03H 17/06; H03H 17/02

(52) U.S. Cl. CPC H03H 17/06; H03H 17/0294; H03H 2017/0081

(57) ABSTRACT

The present invention discloses a method for determining FIR digital filter coefficients providing a compensated amplitude response of a conventional windowing filter. The compensation allows independent control of passband and stopband specifications, while narrowing the transition bandwidths. The method comprises the steps of summing an auxiliary impulse response to a windowing impulse response, wherein the auxiliary impulse response has a phase response identical to that of the windowing impulse response, and an amplitude response comprising frequency shifted pulses positioned to induce the required compensation. The summing is followed by a modulation with a discrete time function to obtain the filter impulse response. The invention discloses a characterization of the pulse compensation on the amplitude response, a filter design method and computer program based on this characterization. The invention discloses an FIR filter device with coefficients set by this method.

### 1. TECHNICAL FIELD OF THE INVENTION

The present invention relates to the field of digital signal processing. Specifically, it relates to finite impulse response (FIR) digital filters, and a novel method for setting their coefficients.

### 2. BACKGROUND ART

Digital filters play a central role in digital signal processing (DSP) which is one of the foundations of modern electronics technology. The use of linear phase digital filters is significant in applications requiring preserving the integrity of the time domain signal profile by minimizing distortions. Such applications might include digital communications, digital audio-visual signal processing, loT devices, VUI systems, and digital flight control systems. It is known in the art that certain FIR digital filter types exhibit an exact linear phase response and are therefore well suited for such applications.

Several circuit configurations are known in the art for realizing an FIR digital filter. FIG.1 represents the circuit configuration of a transversal type cascaded delay line structure for realizing a linear phase FIR filter. In circuit (1), the filter order is M and the number of taps is M+1, and there are M delay units (2-1 to 2-M) connected in cascade constituting a shift register. The filter input x[i] enters the first delay unit through terminal T1. Each delay unit z⁻¹=e^{-jω}, delays the input signal by one sampling period. The output of each delay unit is multiplied by a perspective multiplier h[n], where there are M+1 multiplier, (3-0 to 3-M). All multiplier outputs are added together in an adder circuit (4), where the output of the adder is the filter output y[i] at terminal T2.

The circuit described in FIG. 1 serves to implement the following equation relating the delayed inputs and the output

y[i]=Σₙ₌₀^{M}h[n]x[i−n], (1)

where the current output y[i] is the summation of M+1 present and past inputs. The coefficient sequence h[n] is identified as the finite impulse response of this filter. Letting \tilde{X}(z) and \tilde{Y}(z) be the complex valued z-transforms of the input and output signals, respectively, equation (1) becomes

$$\tilde{Y} ( z ) = {\sum }_{n = 0}^{M} h [ n ] {z}^{- n} \tilde{X} ( z ) = \tilde{H} ( z ) \tilde{X} ( z )$$

with the complex transfer function \tilde{H}(z) of the filter being defined as

$$\tilde{H} ( z ) = \frac{\tilde{Y} ( z )}{\tilde{X} ( z )} = {\sum }_{n = 0}^{M} h [ n ] {z}^{- n} .$$

Herein, the real-valued impulse response h[n] appears as the Inverse z-transform of \tilde{H}(z). It is customary to define the magnitude |\tilde{H}(z)|=|\tilde{H}(e^{jω}) as the positive-valued amplitude response, and the argument arg(\tilde{H}(z))=arg\tilde{H}(e^{jω}) as the phase response. The real-valued zero-phase amplitude response, denoted as H(ω), can be defined for symmetric h[n] as

$$H ( ω ) = {\sum }_{n = 0}^{M} h [ n ] {e}^{- jn ω} {e}^{j \frac{M}{2} ω} .$$

An FIR filter has a linear phase response if its impulse response h[n] is either even-symmetric or odd-symmetric in structure. Furthermore, the impulse response h[n] is real-valued only if |\tilde{H}(e^{jω})| is even-symmetric in frequency.

There are a few ways known in the art to design a linear phase band selective FIR filter, among which the windowing method has had historical significance. The method relies on first finding the ideal impulse response of an idealized model of the magnitude response of the filter. As an example, the magnitude response of an ideal low-pass filter can be defined as

$$\vert ( {e}^{j ω} ) \vert = \{ \begin{matrix}1 & - {ω}_{C} < ω < {ω}_{C} \\ 0 & elsewhere\end{matrix} , \qquad ( 2 )$$

where ±ω_{c} are symmetric cutoff frequencies. This magnitude response is therefore even-symmetric giving a real-valued ideal impulse response h_{ideal}[n]. Applying the Inverse Discrete Time Fourier Transform (IDTFT) gives

$${h}_{ideal} [ n ] = \frac{{ω}_{c}}{π} sin c ( n {ω}_{c} ) . \qquad ( 3 )$$

This ideal impulse response has infinite length and is acausal being centered around n=0. The next step is truncating it to finite length M+1 and modulating it by applying a window function w[n], where there is a plethora of such functions used in the art. The impulse response becomes h_{w}[n]=h_{ideal}[n]×w[n]. Next, for the case M is an even number, the impulse response is shifted by half of the filter order M/2, thereby making the impulse response causal and centered around M/2. The resulting causal windowed impulse response becomes

$${h}_{w} [ n ] = {h}_{ideal} [ n - \frac{M}{2} ] \times w [ n - \frac{M}{2} ] = \frac{{ω}_{c}}{π} sin c ( ( n - \frac{M}{2} ) {ω}_{c} ) \times w ( n - \frac{M}{2} ) . \qquad ( 4 )$$

The transfer function of this practical windowed filter [symbol] (e^{jω}) is calculated as the Discrete Time Fourier Transform (DTFT) of h_{w}[n]

[symbol]

(e^{jω})=Σₙ₌₀^{M}h_{w}[n]e^{-jnω}.

Because this is only a finite term transform, and because of the Gibbs phenomenon, | [symbol] (e^{jω})| can only be an approximation of | [symbol] (e^{jω})|. In general, the larger the filter length M+1 (the number of taps), the more accurate | [symbol] (e^{jω})| will resemble the ideal filter (except for the Gibbs phenomenon which is an intractable problem for the discontinuous model used). Practical considerations require using the smallest number of taps to satisfy a set of filter specifications.

FIG. 2 shows the practical tolerance scheme for the specifications of a low-pass filter. δ₁ and δ₂ are the passband ripple and stopband attenuation, respectively. A disadvantage of the windowing method is that δ₁=δ₂, resulting in the inability to have independent control of passband and stopband characteristics. For many applications, much higher values of δ₁ can be tolerated than for δ₂, and setting the parameters to be equal forces the transition bandwidth, Δω=ωₛ−ωₚ to be wider than could be otherwise. A higher number of filter taps are needed to reduce the transition bandwidth, wherein a narrow transition bandwidth is an important design goal for reducing signal noise and distortion.

An alternative method popular in the art for the independent control of passband and stopband specifications is the Parks-McClellan method based on the iterative Remez exchange algorithm. Herein, the maximum tolerance errors in the filter bands are minimized in the Chebyshev equiripple sense. The method is optimal for obtaining the minimum number of taps to realize any target set of specifications. However, the method has the disadvantage that the iterative algorithm employed is not always guaranteed to converge. Another disadvantage of the Parks-McClellan method is having the built-in artifact of passband equiripple behavior which introduces a level of distortion to the filtered signal. In addition, concern has been expressed that the passband ripples cause pre-echoes and post-echoes in the time domain impulse response with noticeable undesirable effects (Multirate Signal Processing for Communication Systems, Fredrick Harris, Prentice Hall PTR, 2004 and Dunn, Julian. “Anti-Alias and Anti-Image Filtering: The Benefits of 96 kHz Sampling Rate Formats for those who cannot hear above 20 kHz” AES 104th Convention, May 16-19, 1998. Amsterdam, The Netherlands. Preprint 4734).

For the reasons discussed in [0010], methods have been proposed to modify the Remez algorithm to produce flatter passbands (K. Steiglitz, “Optimal design of FIR digital filters with monotone passband response,” IEEE Trans. Acoust., Speech, Signal Processing, vol. ASSP-27, pp. 643-649, December 1979, and P. P. Vaidyanathan Optimal Design of Linear-Phase FIR Digital Filters with Very Flat Passbands and Equiripple Stopbands, IEEE Transactions on Circuits and Systems, VOL. CAS-32, NO. 9, 1985 and FIR Filter and setting Method of Coefficients Thereof, Y. Mogi, K. Nishibori, Soni Corporation, USOO7028061B2).

The present invention provides a method for designing narrow transition bandwidth FIR filters, based on the windowing method, characterized by having passbands that are flatter than Parks-McClellan equiripple filters, being free from the equiripple artefact.

### 3. INVENTION SUMMARY

A major aspect of this invention is producing a finite impulse response h[n] representing a modification of a conventional windowing impulse response h_{w}[n], wherein a compensated impulse response h_{c}[n] is first obtained by summing an auxiliary impulse response hₐ[n] to the windowing impulse response h_{w}[n] to obtain h_{c}[n]=h_{w}[n]30 hₐ[n], wherein h_{c}[n] may be subject to further manipulation. The auxiliary impulse response hₐ[n] is purposefully selected as to induce sought improvements in the filter amplitude response.

According to another aspect of the present invention, the finite impulse response of the filter h[n] is obtained by applying a discrete time modulation m[n] to the compensated impulse response as h[n]=m[n]×h_{c}[n], written alternatively as

h[n]=m[n]×(h_{w}[n]+hₐ[n])=m[n]×h_{w}[n]+m[n]×hₐ[n].

According an embodiment of this invention, the said discrete time modulation maybe an identity modulation, in which case m[n]=1, resulting in h[n]=h_{c}[n].

Another aspect of this invention is using the windowing impulse response h_{w}[n] as a starting point in the process for obtaining h[n]·h_{w}[n] can be calculated in the prior art manner described by equations (2)-(4) for the case of a low-pass filter. However, h_{c}[n] is not limited to only this type of filter, any ideal even-symmetric magnitude response [symbol] (e^{jω}) could be used to obtain a corresponding ideal impulse response h_{ideal}[n], followed by the application of a window function w[n].

Another aspect of this invention is that hₐ[n] and h_{w}[n] can always be made to have the same length M+1. A unified length is needed to perform the sum h_{w}[n]+hₐ[n]. Starting with impulse responses hₐ[ ] and h_{w}[ ] that are not of the same length, zero-valued impulses can be added at the edges of the shorter of the two as needed to increase its length to be the same as the longer one (zero padding).

Another aspect of this invention is using an auxiliary impulse response hₐ[n] having an auxiliary transfer function [symbol] (e^{jω})=Σₙ₌₀^{M}a[n]e^{-jnω} with a phase response that is identical to the phase response of the transfer function of the windowed impulse response [symbol] (e^{jω})=Σₙ₌₀^{M}h_{w}[n]e^{-jnω}), thereby enabling a well-defined interference of the amplitude responses of the two transfer functions upon the sum h_{w}[n]+hₐ[n].

Another aspect of the invention that follows from is that the compensated transfer function [symbol] (e^{jω}) given by the compensated impulse response h_{c}[n], and being equal to [symbol] (e^{jω})= [symbol] (e^{jω})+ [symbol] (e^{jω}), has a zero-phase amplitude response that is the sum of the zero-phase amplitude responses, H_{c}(ω)=H_{w}(ω)+Hₐ(ω). This well-defined interference allows for straightforward setting the input parameters of Hₐ(ω) and H_{w}(ω) to achieve the desired response of H_{c}(ω).

According to an embodiment of the present invention the transfer function of the filter \tilde{H}(e^{jω}) may be calculated as the convolution of the DTFT of the discrete time modulation function \tilde{M}(e^{jω})with the compensated transfer function [symbol] (e^{jω}), namely \tilde{H}(e^{jω})=\tilde{W}(e^{jω})* [symbol] (e^{jω}). In this case, the impulse response of the filter h[n] is obtained as the IDTFT of \tilde{H}(e^{jω}).

Another aspect of this invention is using an auxiliary impulse response hₐ[n] producing an auxiliary amplitude response Hₐ(ω) comprising a plurality of pulses, each with a dominant central lobe and weaker side lobes, or an amplitude response being the sum or difference of the said plurality of pulses.

Another significant aspect of this invention is using an auxiliary impulse response hₐ[n] producing an auxiliary amplitude response Hₐ(ω) having pulses with dominant central lobes that interfere with the windowed amplitude response H_{w}(ω) in the transition band regions, increasing the magnitude of the transition slopes and inducing faster transitions between the filter bands, thereby reducing the bandwidth of the transition bands.

Another significant aspect of this invention is using of an auxiliary impulse

response hₐ[n] producing an auxiliary amplitude response Hₐ(ω) having pulses with weak side lobes that interfere destructively with the stopband ripples of the windowed amplitude response H_{w}(ω) close to the transition band edge, thereby increasing stopband attenuation.

A preferred embodiment of this invention is using an auxiliary impulse response hₐ[n] having an even-symmetric structure, and having the functional profile of one of the window functions known in the art. Such a specification yields an amplitude response having the said multi-lobed pulse forms. The pulse height, width and position on the frequency axis are controllable by independent parameters in the mathematical description of the said function. Moreover, being even symmetric, hₐ[n] can produce a linear phase response.

Another preferred embodiment of this invention is using an auxiliary impulse response hₐ[n] that is based on the rectangular window (Dirichlet window) defined by

$${h}_{a\_dirichlet} [ n ] = \{ \begin{matrix}1 & 0 \leq n \leq m \\ 0 & elsewhere\end{matrix} ,$$

and generating an auxiliary transfer function [symbol] (e^{jω}) having a zero-phase amplitude response H_{a_dirichlet}(ω), known as a Dirichlet Kernel, which is given by

$${H}_{a\_dirichlet} ( ω ) = \frac{sin ( \frac{M + 1}{2} ω )}{sin ( \frac{1}{2} ω )} .$$

This amplitude response has the required multi-lobe pulse form of the embodiments above. The Dirichlet Kernel has zeroes on the frequency axis located at

$$ω = \frac{2 π k}{M + 1} with k = \pm 2 , \pm 3 , … , M .$$

Another significant aspect of this invention is prescribing a mathematical means for frequency shifting the pulses of the amplitude response Hₐ(ω) of the auxiliary impulse response hₐ[n] on the frequency axis so that they are positioned strategically to have the desired interference effects mentioned in [0022] and [0023]. This is achieved by using the known procedure of applying a phase modulation to the discrete time domain impulse response hₐ[n], resulting in a frequency shift of the transfer function [symbol] (e^{jω}) in the frequency domain, as given by the transformation equation

$${e}^{j {ω}_{o} ( n - \frac{M}{2} )} {h}_{a} [ n ] ⇔ ( {e}^{i ( ω - {ω}_{o} )} ) ,$$

with ωₒ being the value of the frequency shift.

Another aspect of this invention that is necessary for any real-valued impulse response, is having the pulses of the auxiliary amplitude response Hₐ(ω) to occur in pairs, wherein the pair members are symmetrically shifted to opposite sides of the symmetry axis centered at zero frequency by equal magnitude frequency shifts ±ωₒ. This is achieved by applying the method in to create the said pair of pulses, with the auxiliary impulse response set to be even-symmetric as

$${h}_{a} [ n ] ⇒ \frac{1}{2} {e}^{+ j {ω}_{o} ( n - \frac{M}{2} )} \times {h}_{a} [ n ] + \frac{1}{2} {e}^{- j {ω}_{o} ( n - \frac{M}{2} )} \times {h}_{a} [ n ] = cos ( ( n - \frac{M}{2} ) {ω}_{o} ) \times {h}_{a} [ n ] .$$

A preferred embodiment of this invention is producing the pulse pair of [0027] by using the Dirichlet impulse response of [0025]. The auxiliary impulse response hₐ[n] becomes

$${h}_{a} [ n ] = cos ( ( n - \frac{M}{2} ) {ω}_{o} ) \times {h}_{a\_dirichlet} [ n ] = \{ \begin{matrix}cos ( ( n - \frac{M}{2} ) {ω}_{o} ) & 0 \leq n \leq M \\ 0 & elsewhere\end{matrix} .$$

This gives an auxiliary transfer function [symbol] (e^{jω}) defining a pair of frequency shifted Dirichlet pulses in its zero-phase amplitude response Hₐ(ω) given by

$${H}_{a} ( ω ) = {ε}_{o} ( \frac{sin ( \frac{M + 1}{2} ( ω + {ω}_{o} ) )}{sin ( \frac{1}{2} ( ω + {ω}_{o} ) )} + \frac{sin ( \frac{M + 1}{2} ( ω - {ω}_{o} ) )}{sin ( \frac{1}{2} ( ω - {ω}_{o} ) )} ) .$$

The factor εₒ serves to scale symmetrically the amplitudes of the pulse pair.

One embodiment of this invention is using an auxiliary impulse response hₐ[n] providing one frequency shifted Dirichlet pulse for each transition band in the windowed amplitude response H_{w}(ω), where this situation is henceforth referred to as a “singlet”. The windowed amplitude response H_{w}(ω) must be even-symmetric for a real-valued impulse response, resulting in that the transition bands occur in pairs. Therefore, a “singlet” situation involves using an auxiliary amplitude response Hₐ(ω) that includes the terms

$${ε}_{o} ( \frac{sin ( \frac{M + 1}{2} ( ω + {ω}_{o} ) )}{sin ( \frac{1}{2} ( ω + {ω}_{0} ) )} + \frac{sin ( \frac{M + 1}{2} ( ω - {ω}_{0} ) )}{sin ( \frac{1}{2} ( ω - {ω}_{o} ) )} ) ,$$

with one of the pulse pair members being used for each member of the said transition band pairs. For a one-pair transition band filter, such as a low-pass or high-pass filter, the auxiliary impulse response that produces a singlet becomes,

$${h}_{a , singlet} [ n ] = \{ \begin{matrix}{ε}_{o} cos ( ( n - \frac{M}{2} ) {ω}_{o} ) & 0 \leq n \leq M \\ 0 & elsewhere\end{matrix}$$

Another embodiment of this invention is using an auxiliary impulse response hₐ[n] providing the difference of two adjacent frequency shifted Dirichlet pulses for each transition band in the windowed amplitude response H_{w}(ω), this situation is henceforth referred to as a “doublet”. The auxiliary amplitude response Hₐ(ω) in this case will include the terms

$$( {ε}_{0} \frac{sin ( \frac{M + 1}{2} ( ω + {ω}_{o} ) )}{sin ( \frac{1}{2} ( ω + {ω}_{o} ) )} - {ε}_{1} \frac{sin ( \frac{M + 1}{2} ( ω + {ω}_{1} ) )}{sin ( \frac{1}{2} ( ω + {ω}_{1} ) )} ) + ( {ε}_{0} \frac{sin ( \frac{M + 1}{2} ( ω + {ω}_{o} ) )}{sin ( \frac{1}{2} ( ω + {ω}_{o} ) )} - { ε}_{1} \frac{sin ( \frac{M + 1}{2} ( ω - {ω}_{1} ) )}{sin ( \frac{1}{2} ( ω - {ω}_{1} ) )} )$$

with ω₁ being the shift of the second pulse pair, and the factor ε₁ serves to scale symmetrically their amplitudes. Therefore, a “doublet” situation involves using the two pulses inside each bracket of the expression above for each of the said transition band pair members. For a one-pair transition band filter, such as a low-pass or high-pass filter, the auxiliary impulse response that produces a doublet becomes,

$${h}_{a , doublet} [ n ] = \{ \begin{matrix}{ε}_{o} cos ( ( n - \frac{M}{2} ) {ω}_{o} ) - {ε}_{1} cos ( ( n - \frac{M}{2} ) {ω}_{1} ) & 0 \leq n \leq M \\ 0 & elsewhere\end{matrix} \qquad ( 5 )$$

Another preferred embodiment of this invention is using an auxiliary impulse response hₐ[n] producing an amplitude response Hₐ(ω) that is designed to have one of its zeroes match the frequency of each of the cutoff frequencies in the amplitude response of the windowed impulse response H_{w}(ω).

Paragraphs [13]-[31] provide disclosure to produce the FIR impulse response of the invention, h[n]. For h[n] to be effective in obtaining filters of required performance, suitable choices must be made for the values of the independent parameters in its mathematical expression of h[n]. An aspect of the present invention is providing a method for setting the values of the independent parameters to achieve the required filter performance.

An aspect of this invention is to provide a method for determining the characteristics of an FIR digital filter with coefficients set to the impulse response of the invention h[n]. This is done by carrying out a plurality of numerical computer simulations to generate the transfer function of the filter \tilde{H}(e^{jω})=Σₙ₌₀^{M}h[n]e^{-jnω}, from which the magnitude response |\tilde{H}(e^{jω})| can be determined.

Another aspect of this invention is to perform the said simulations with input parameters set to be the independent parameters defining the mathematical description of h[n]. These are identified to be the length of the windowed impulse response M+1, the cutoff frequencies of the windowed amplitude response ω_{c}, the pulse frequency shifts ωₒ and ω₁, the pulse amplitude parameters εₒ and ε₁, and the input parameters of an adopted windowing design method, wherein the Kaiser window design method serves as a non-limiting preferred embodiment, with transition bandwidth Δ, stopband attenuation SB, and passband ripple PB, being the input design parameters.

Another aspect of this invention is producing the said plurality of transfer function simulations, wherein the input parameter values are stepped iteratively, in discretized selected ranges that are unique to each parameter, whereby the simulations cover the chosen input parameter combinations. The magnitude response |\tilde{H}(e^{jω})| for each transfer function is calculated, and the set of the output filter characteristics for each amplitude response are determined. The output filter characteristics include the magnitude of the band gain, the peak to peak ripple, and the transition bandwidth, of all bands and transition regions of the magnitude response |\tilde{H}(e^{jω})|. The output filter characteristic sets and the input parameters sets that produce them are recorded in computer data files which are used to plot families of multi-variable graphs of the interdependence between the input parameters and output characteristics. Graphical analysis is performed on the said graphs by applying a mathematical technique of multi-variable curve fitting, whereby generating a plurality of interpolation formulae that model the mapping of the input parameters to the output characteristics;

Paragraphs [33]-[35] provide disclosure of the process for obtaining the necessary filter characteristics data to be used for designing an FIR digital filter based on the aspects and embodiments of this invention.

Another aspect of this invention is a design process for an FIR digital filter having a target set of filter specifications. The design process depends on the type of filter sought which might include, but is not limited to the low-pass, high-pass, band-pass and band-reject varieties. The design process also depends on the choice of the embodiments of the auxiliary impulse response hₐ[n], including the choice of the window function, whether a singlet design or a doublet design is used, and whether zero alignment to cutoff frequency is implemented ([0031]).

Another aspect of this invention is a design process, notwithstanding the particularities mentioned in [0037], comprising the generalized steps of:
a) assigning the values of the target set of filter specifications to be a set of output characteristics, wherein these are used in conjunction with the said multi-variable interpolation formulae to calculate the specific set of input filter parameters that will produce the target filter characteristics;
b) calculating the impulse response of the invention h[n], by using the said specific set of input parameters; and
c) setting the filter coefficient sequence to be equal to the impulse response of the invention h[n], whereby the said coefficient sequence is used to realize the filter.

Another aspect of the invention is the implementation of the filter characterization and design method [0038] of the preferred embodiment of this invention by a computer program, whether being custom-written or implemented on a commercial software platform, in any computer language.

Another aspect of this invention is a computer program to emulate numerically the filtering action of an FIR digital filter, by calculating the transfer function of the filter using filter coefficients designed by the methods of this invention, and then using this transfer function to filter a discrete time input signal, thereby obtaining the output signal.

An important aspect of the present invention aims to design an FIR filter circuit having the direct form delayed line structure of FIG. 1, wherein the coefficients of the filter are equivalent to the finite impulse response described as being determined by a process that is an aspect of this invention. The digital filter circuit comprises M cascaded z⁻¹ time delay units, M+1 filter coefficient multipliers, M multipliers being connected to input terminals of the corresponding time delay units and the remaining multiplier being connected to an output terminal of the last time delay unit, and an adder connected to output terminals of the M multipliers.

The present invention is described further as being a non-iterative method for

designing an FIR filter claiming advantages of both the windowing method and the Parks-McClellan equiripple method. The filter of the invention, compared to two other filters of the mentioned types having the same set of filter specifications, provides: (i) a passband lacking the equiripple artefact, being as flat as the windowing filter with only half of a ripple cycle to one ripple cycle depending on the number of auxiliary pulses used, (ii) a transition response slope almost identical to that of the equiripple filter, (iii) a larger attenuation in the deep stopband compared to the equiripple filter, and (iv) unlike the equiripple method which relies on convergence conditions for achieving the set specifications where convergence is not guaranteed, precise values of the specifications can be implemented with the method of the invention. The cost of achieving these advantages is a relatively small increase in the number of filter taps over to the optimal Parks-McClellan equiripple filter, when compared to the number of taps required by the windowing filter. Generally, the filter of the invention requires about only one third of the extra taps needed by the windowing filter, but can be even less depending on the specifications.

### 4. BRIEF DESCRIPTION OF THE DRAWINGS

So that the manner in which the above recited features of the present disclosure can be understood in detail, a more particular description of the disclosure, may have been referred by embodiments, some of which are illustrated in the appended drawings. It is to be noted, however, that the appended drawings illustrate only typical embodiments of this disclosure and are therefore not to be considered limiting of its scope, for the disclosure may admit other equally effective embodiments.

These and other features, benefits, and advantages of the present disclosure will become clearer by reference to the following figures , wherein:

FIG. 1 illustrates a low-pass filter employing the transversal type cascaded direct delay line structure, in accordance with prior art;

FIG. 2 shows the tolerance scheme for the specifications of a low-pass filter;

FIG. 3a and FIG. 3b illustrate the zero-phase amplitude responses of a low-pass

rectangular window impulse response, the doublet auxiliary impulse response and the compensated impulse response;

FIG. 4 illustrates simulation results for SB_{F} vs. PB for different values of SB;

FIG. 5 illustrates simulation results for Δ_{F} vs. PB for different values of SB;

FIG. 6 illustrates simulation results for εₘₐₓ vs. Δ for different values of SB;

FIG. 7 illustrates simulation results for ε_{F} vs. PB for different values of SB;

FIG. 8 illustrates simulation results for μ vs. PB for different values of SB;

FIG. 9a and FIG. 9b show the linear-scale magnitude response of the preferred embodiment for a low-pass filter and that of a Parks-McClellan equiripple filter;

FIG. 10a and FIG. 10b show the linear-scale magnitude response of the preferred

embodiment for a low-pass filter and that of a Kaiser windowing filter;

FIG. 11a and FIG. 11b show the dB scale magnitude responses of the preferred embodiment for a low-pass filter, a Parks-McClellan equiripple filter and a Kaiser windowing filter;

FIG. 12 shows the tap savings fraction vs. stopband attenuation for two values of passband ripple for two design requirements;

FIG. 13 shows an embodiment of the invention for a band-pass filter;

FIG. 14 shows an embodiment of the invention for a band-stop filter; and

FIG. 15 shows the singlet, doublet and triplet embodiments of a low-pass filter passband.

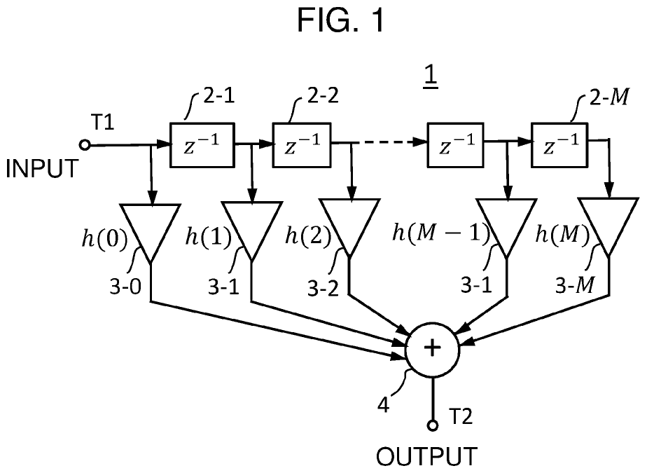

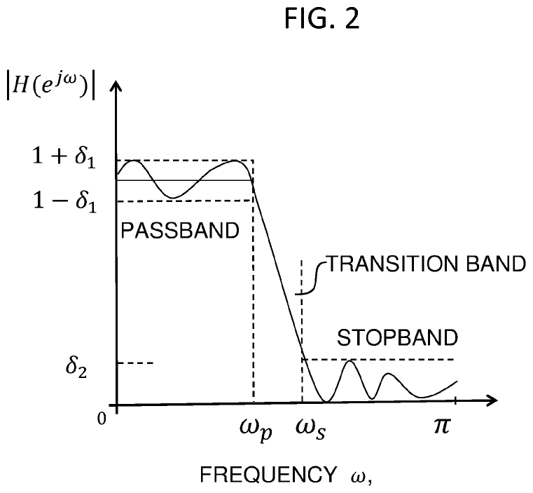

### 5. DESCRIPTION OF THE PREFERRED EMBODIMENT

Detailed embodiments of the preferred mode are described herein; however, it is to be understood that such embodiments are exemplary of the present disclosure, which may be embodied in various alternative forms. Specific process details disclosed herein are not to be interpreted as limiting, but merely as a representative basis for teaching one skilled in the art to variously employ the present disclosure in any appropriate process.

The terms used herein are for the purpose of describing exemplary preferred

embodiments only and are not intended to be limiting. As used herein, the singular forms “a,” “an,” and “the” are intended to include the plural forms as well, unless the context clearly indicates otherwise. It will be further understood that the described methods and mathematical forms do not preclude the presence or addition of one or more steps, terms or operations other than a mentioned step, term or operation.

The embodiments of the present disclosure will now be described more fully hereinafter with reference to the accompanying drawings, which form a part hereof, and which show, by way of illustration, specific example embodiments.

### 5.1 The Preferred Embodiment of a Low-Pass Filter

The detailed description of the preferred embodiment includes the design of a low-pass filter. But it is understood that the methods and mathematical formulae of the invention are not limited to this filter type only but can be applied as effectively to other types of band selective filters such as high-pass, band-pass band-stop and other designs.

A preferred mode for a low-pass filter is to assign h_{w}[n] to be the rectangular window impulse response applied to equation (4), which becomes

$${h}_{w} [ n ] = 2 {f}_{c} \times sin c ( 2 π {f}_{c} ( n - \frac{M}{2} ) ) = 2 {f}_{c} \times \frac{sin ( 2 π {f}_{c} ( n - \frac{M}{2} ) )}{2 π {f}_{c} ( n - \frac{M}{2} )} ,$$

with n running from 0 to M, and f_{c} being the normalized cutoff frequency (in Hz),

$${f}_{c} = \frac{{ω}_{c}}{2 π} .$$

Also, a preferred mode is to assign the auxiliary impulse response hₐ[n] to be the “doublet” impulse response given in equation (5), and rewritten here as

$${h}_{a , doublet} [ n ] = {ε}_{o} cos ( 2 π ( n - \frac{M}{2} ) {f}_{o} ) - {ε}_{1} cos ( 2 π ( n - \frac{M}{2} ) {f}_{1} ) \qquad ( 6 )$$

with n running from 0 to M. This impulse response gives an auxiliary amplitude response having the two pairs of Dirichlet pulses for each of the pairs of transition bands, as explained in [0030].

The frequency shifts fₒ and f₁ appearing in equation (6) are assigned the values

$${f}_{o} = {f}_{c} - \frac{1}{M + 1} and {f}_{1} = {f}_{c} - \frac{2}{M + 1} .$$

to make both the first zero of the first pulse, and the second zero of the inverted second pulse to coincide in frequency with the cutoff frequency f_{c}.

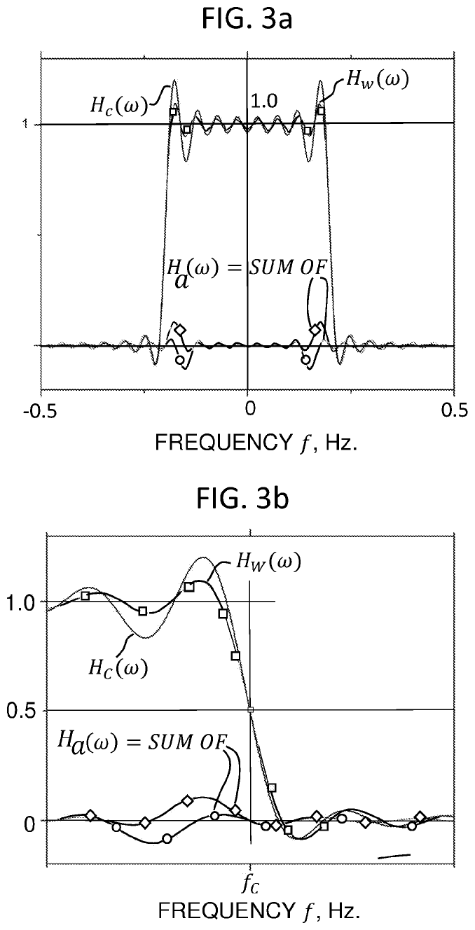

To exemplify the action of the auxiliary impulse response embodiment, reference is made to FIG. 3a, with expanded view for positive frequencies in FIG. 3b. They illustrate the zero-frequency amplitude responses of the impulse responses h_{w}[n], hₐ[n] and the compensated impulse response h_{c}[n], wherein these amplitude responses have been designated as H_{w}(ω), Hₐ(ω) and H_{c}(ω), respectively. The identical phase relationship among them permits writing H_{c}(ω)=H_{w}(ω)+Hₐ(ω), as explained in [0019]. It is evident from FIG. 3b that Hₐ(ω) has the desired effect of increasing the magnitude of the slope of the compensated response in the transition band. In the figure, the pulse amplitudes have been exaggerated for clarity. Furthermore, the passband ripple is observed to be amplified.

The next crucial step in the method is the application of the discrete time modulation m[n], acting as a frequency domain averaging that diminishes both the stopband and the amplified passband ripples of the amplitude response of the filter.

Also, a preferred mode is to assign the discrete time modulating function m[n] to be defined as a zeroth-order Bessel function of the first kind (also known as Kaiser window) given in normalized form as:

$$m [ n ] = \frac{{I}_{o} [ β \sqrt{1 - {( \frac{n - \frac{M}{2}}{\frac{M}{2}} )}^{2}} ]}{{I}_{0} [ β ]} ,$$

with n running from 0 to M, and with Iₒ being the symbol for the zeroth order Bessel function, β is a bandwidth parameter, and M is the filter order. Reference is made to the equation h[n]=m[n]×(h_{w}[n]+hₐ[n]) in [0014] which defines the impulse response of the filter h[n] as

h[n]=m[n]×h_{w}[n]+m[n]×hₐ[n].

The first term m[n]×h_{w}[n] , being expanded as

$$m [ n ] \times {h}_{w} [ n ] = 2 {f}_{c} \frac{{I}_{o} [ β \sqrt{1 - {( \frac{n - \frac{M}{2}}{\frac{M}{2}} )}^{2}} ]}{{I}_{0} [ β ]} \times \frac{sin ( 2 π {f}_{c} ( n - \frac{M}{2} ) )}{π ( n - \frac{M}{2} )} .$$

is exactly the impulse response of a low-pass filter of the Kaiser windowing method. The second term m[n]×hₐ[n] expanded as

$$m [ n ] \times {h}_{a} [ n ] = \frac{{I}_{o} [ β \sqrt{1 - {( \frac{n - \frac{M}{2}}{\frac{M}{2}} )}^{2}} ]}{{I}_{o} [ β ]} \times ( {ε}_{o} cos ( 2 π ( n - \frac{M}{2} ) {f}_{o} ) - {ε}_{1} cos ( 2 π ( n - \frac{M}{2} ) {f}_{1} ) ) ,$$

gives an amplitude response having two pulses each of which corresponds to a frequency shifted DTFT of the Kaiser window.

It is concluded from the description in [0069] that the preferred embodiment under consideration is tantamount to a Kaiser windowing method for a low-pass filter that is compensated by two frequency shifted Kaiser window DTFT pulses in each transition band of the filter. A design method can therefore be pursued based on the Kaiser window design method, which is well known in the art. This method stipulates that a low-pass filter having a stopband attenuation SB and a transition bandwidth Δ, can be realized by a filter of order M and window bandwidth parameter β, being given by the two equations

$$M = \frac{S B - 8.0}{2.285 Δ}$$

$$β = \{ \begin{matrix}0.11 02 ( S B - 8 \text{.7} ) & SB > 50 \\ 0.58 42 {( S B - 21 )}^{0.4} + 0.07886 ( S B - 21 ) & 21 \leq SB \leq 50 \\ 0. & SB \leq 21\end{matrix} .$$

The Kaiser window filter passband ripple is designated PB_{K}, and is given by the expression, PB_{K}=20 log(1+δ) with

$$δ = 1 {0}^{\frac{- S B}{20}} .$$

The inclusion of the auxiliary doublet pulses in the amplitude response of the Kaiser window filter has the effect of narrowing the transition bandwidth Δ, and increasing the stopband attenuation SB for a wide range of design values. This occurs at the expense of introducing exactly one prominent passband ripple cycle at the transition band edge, wherein the ripple is larger in magnitude than the characteristic Kaiser window filter passband ripples. This is something that can be tolerated to a certain extent as explained in [0009].

### 5.1.1 Characterization of a Filter

Also, the preferred embodiment outlines a method for quantifying the effect of the doublet pulse amplitude parameters εₒ and ε₁ on the filter characteristics. First, it is emphasized that εₒ, the amplitude of the first pulse, is treated as an independent parameter, while ε₁, being the amplitude of the second pulse, is treated as a dependent parameter related to εₒ by the relation ε₁=μεₒ. Here, μ is called the symmetry parameter, and has a typical value in the range 0.3-0.7, being also dependent on SB. According to the present embodiment, μ is adjusted such that the two opposite peaks of the said prominent single passband ripple are symmetrical about their mean passband value.

Also, the preferred embodiment includes performing computer simulations for calculating the filter transfer function \tilde{H}(e^{jω}) from the filter impulse response h[n] by applying the DTFT, from which the magnitude response |\tilde{H}(e^{jω})| is calculated. The filter characteristics comprises the filter's actual passband ripple peak PBₒᵤₜ, the actual transition bandwidth Δₒᵤₜ and the actual stopband attenuation SBₒᵤₜ. These characteristics are determined from the magnitude response |\tilde{H}(e^{jω})| by using numerical techniques. The magnitude response |\tilde{H}(e^{jω})|, being equal to |H(ω)|, is preferred over the zero-frequency amplitude response H(ω) for the purpose of calculating the characteristics because |\tilde{H}(e^{jω})| is positive definite, thus enabling the use of the standard dB logarithmic scale.

In this preferred embodiment, a broad set of filter characteristics is obtained by iterating the Kaiser window design parameter values SB, Δ and the auxiliary parameter εₒ, while running the said simulations for the transfer function, and calculating and recording the actual (output) filter characteristics PBₒᵤₜ, Δₒᵤₜ and SBₒᵤₜ. The results quantifying the change from the set window filter values to the output values upon the insertion of the auxiliary pulses are given via the fractional change parameters. These are defined as

$$S {B}_{F} = \frac{S {B}_{o u t}}{S B} , and$$

$${Δ}_{F} = \frac{{Δ}_{out}}{Δ} .$$

While for PBₒᵤₜ, it is convenient to give the output value additively via the change in the passband ripple peak PB as

PBₒᵤₜ=PB+PB_{K}, or alternatively PB=PBₒᵤₜ−PB_{K}.

SBₒᵤₜ, Δₒᵤₜ and PBₒᵤₜ converge to SB, Δ and PB_{K}, respectively, for the case εₒ=0, i.e. when the auxiliary impulse response is zero. The parameters SB, Δ and εₒ are stepped in discretized selected ranges that are unique to each parameter. SB is stepped from 35 to 90 dB, Δ is stepped from 0.025 to 0.15 Hz, and εₒ is stepped from zero to a value εₘₐₓ that produces a maximum of PBₒᵤₜ=0.5 dB (1 dB passband peak to peak ripple). A parameter ε_{F} is defined as

$${ε}_{F} = \frac{{ε}_{o}}{{ε}_{max}} .$$

Being directly proportional to εₒ, ε_{F} is instrumental in relating the first pulse amplitude parameter εₒ to the change in the peak passband ripple PB. ε_{F} ranges from 0 to 1, corresponding to a change in PBₒᵤₜ from PB_{K} to 0.5 dB, wherein PB_{K} is a small quantity for most simulations, but still non-negligible in general.

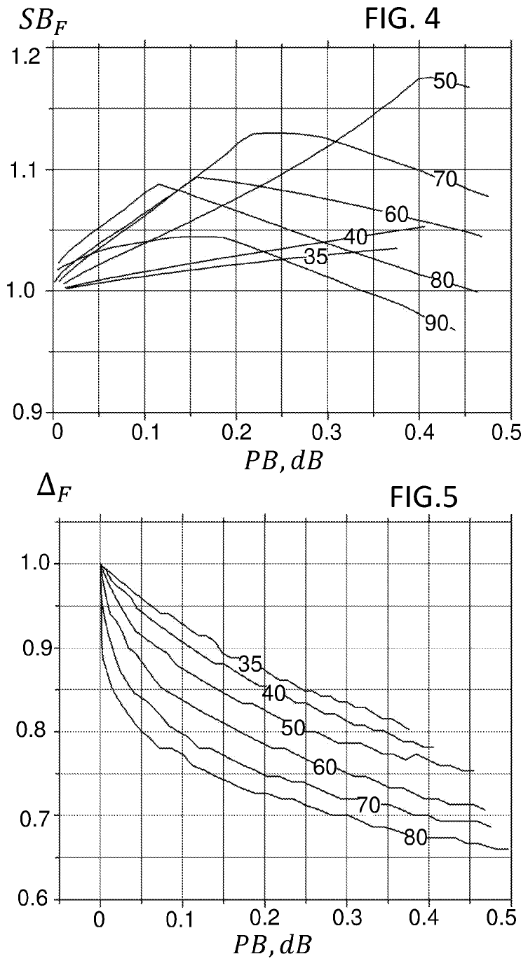

FIG. 4 illustrates simulation results, wherein a set of relationships between SB_{F} and PB are plotted for different values of SB. The numbers (35-90) on the curve lines identify the curve line for the indicated value of SB. The graphs are interpreted as meaning that the inclusion of the auxiliary pulses increases SB_{F} for most simulations, and hence a larger stopband attenuation SBₒᵤₜ of the filter. This is a sought-after effect from the insertion of the auxiliary pulses. The data are plotted as SB_{F} vs. PB, being convenient for obtaining suitable interpolation equations necessary for the design process. The interpolation equations for SB_{F} are obtained in a two variable curve fitting process of SB_{F} (PB, SB) as a function of the two variables PB and SB. It was found that SB_{F} depends minimally on Δ.

FIG. 5 illustrates simulation results, wherein a set of relationships between Δ_{F} and PB are plotted for different values of SB. The numbers (35-80) on the curve lines identify the curve line for the indicated value of SB. The graphs are interpreted as meaning that the larger ε_{F} (the larger the amplitude of the auxiliary pulses) the smaller Δ_{F} , and hence the narrower the transition bandwidth t out of the filter. This is a sought-after effect from the insertion of the auxiliary pulses. The data are plotted as Δ_{F} vs. PB, being convenient for obtaining suitable interpolation equations necessary for the design process. The interpolation equations for ΔF are obtained in a two variable curve fitting process of Δ_{F} (PB, SB) as a function of the two variables PB and SB. It was found that Δ_{F} depends minimally on Δ itself.

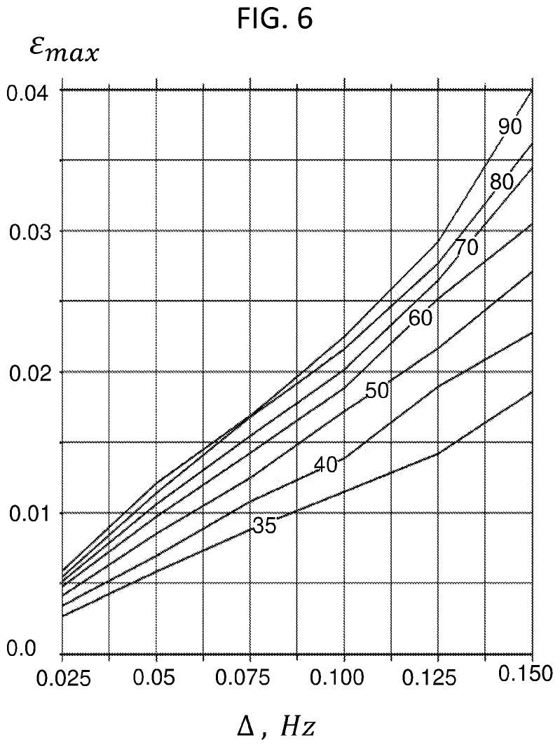

FIG. 6 illustrates simulation results, wherein a set of relationships between εₘₐₓ (introduced in [0074]) and the transition bandwidth Δ are plotted for different values of SB. The numbers (35-90) on the curve lines identify the curve line for the indicated value of SB. The graphs are necessary for determining the pulse amplitudes to use for any specified value of peak passband ripple PBₒᵤₜ. Interpolation equations for εₘₐₓ are obtained in a two variable curve fitting process of εₘₐₓ(Δ, SB) as a function of the two variables Δ and SB.

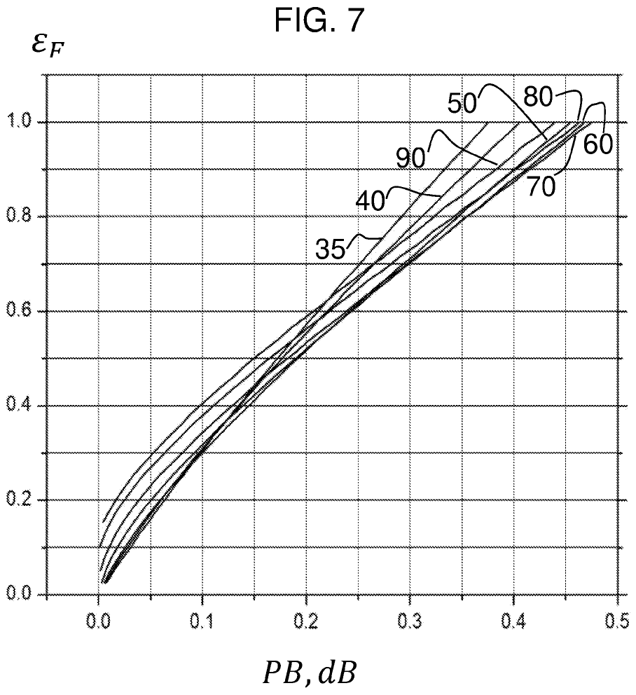

FIG. 7 illustrates simulation results, wherein a set relationship between PB and

the parameter ε_{F} (introduced in [0066]) are plotted for different values of SB. The numbers (35-90) on the curve lines identify the curve line for the indicated value of SB. It is observed that the larger ε_{F} the larger the value of PB. The curve lines can be identified in the lower left half of the graph through their linear extension. The data is plotted in transposed form (i.e. ε_{F} vs. PB), being convenient for obtaining suitable interpolation equations necessary for the design process. The interpolation equations for ε_{F} are obtained in a two variable curve fitting process of ε_{F} (PB, SB) as a function of the two variables PB and SB. It was found that ε_{F} depends minimally on Δ.

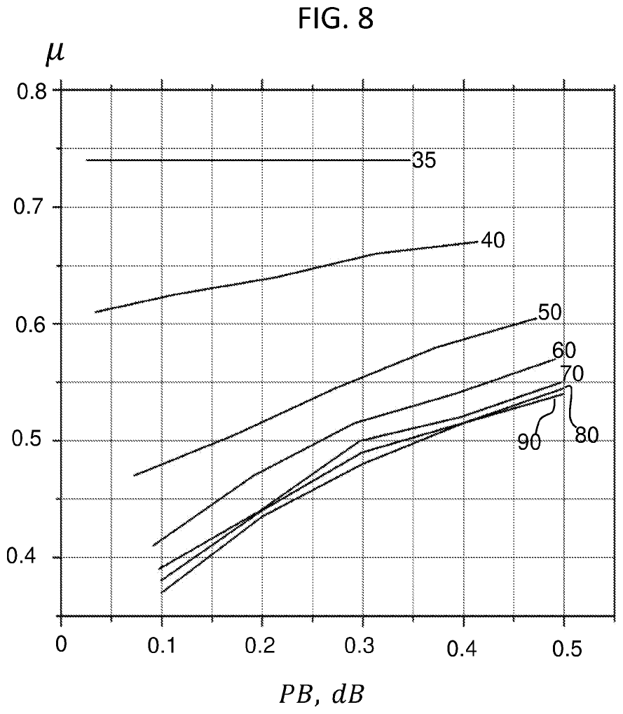

FIG. 8 illustrates simulation results, wherein a set of relationships between the symmetry parameter μ (introduced in [0072]) and PB are plotted for different values of SB. The numbers (35-90) on the curve lines identify the curve line for the indicated value of SB. The graphs are necessary for determining the amplitude of the second pulse necessary to symmetrize the single passband ripple cycle of the doublet design. Interpolation equations for μ are obtained in a two variable curve fitting process of μ(PB,SB) as a function of the two variables PB and SB. It was found that μ depends minimally on Δ.

### 5.1.2 Filter Design Method

The description of the preferred embodiment includes a non-iterative design method that is based on the archived and plotted characteristics for the Kaiser-window-based doublet displayed in FIG. 4-FIG. 8 and the interpolation equations derived from them. The design equations from the preferred description are repeated in the steps listed herein for completeness and for minimizing referencing. The design method, to be performed in the specified order, comprises the steps of:
a) setting the filter target specification PBᵢₙ, SBᵢₙ, fₚ and fₛ;
b) setting the filter output characteristics SBₒᵤₜ=SBᵢₙ, PBₒᵤₜ=PBᵢₙ and Δₒᵤₜ=Δᵢₙ−fₛ−fₚ;
c) estimating SB as SB=SB_{EST}=SBₒᵤₜ, and estimating PB as

$$P B = P {B}_{o u t} - P {B}_{K , EST .} = {PB}_{o u t} - 20 log ( 1 + 1 {0}^{\frac{- S {B}_{EST .}}{20}} ) ;$$

d) applying interpolation equation SB_{F}(PB,SB_{EST}.) of FIG. 4 to find SB_{F} and resetting

$$SB = \frac{S {B}_{o u t}}{S {B}_{F}} , and PB = {PB}_{o u t} - 20 log ( 1 + 1 {0}^{\frac{- S B}{20}} ) ;$$

e) applying interpolation equation Δ_{F}(PB,SB) of FIG. 5 to find

$$Δ = \frac{{Δ}_{o u t}}{{Δ}_{F}} ;$$

f) applying interpolation equation εₘₐₓ(Δ,SB) of FIG. 6 to find εₘₐₓ;
g) applying interpolation equation ε_{F}(PB,SB) of FIG. 7 to find εₒ=ε_{F}×εₘₐₓ;
h) applying interpolation equation μ(PB,SB) of FIG. 8 to find ε₁=μ×εₒ;
i) calculating the filter order

$$M = \frac{S B - 8.0}{2.285 Δ} ;$$

j) setting the frequency parameters

$$\begin{matrix}{f}_{c} = {f}_{s} - \frac{Δ}{2} , & {f}_{o} = {f}_{c} - \frac{1}{M + 1} and\end{matrix} {f}_{1} = {f}_{c} - \frac{2}{M + 1} ;$$

k) calculating the Kaiser bandwidth parameter

$$β = \{ \begin{matrix}0.11 02 ( S B - 8 \text{.7} ) & SB > 50 \\ 0.58 42 {( S B - 21 )}^{0.4} + 0.07886 ( S B - 21 ) & 21 \leq SB \leq 50 \\ 0. & SB \leq 21\end{matrix} ;$$

and
l) calculating the impulse response of the filter

$$h [ n ] = \frac{{I}_{o} [ β \sqrt{1 - {( \frac{n - \frac{M}{2}}{\frac{M}{2}} )}^{2}} ]}{{I}_{o} [ β ]} \times ( \frac{sin ( 2 π {f}_{c} ( n - \frac{M}{2} ) )}{π ( n - \frac{M}{2} )} + {ε}_{o} cos ( 2 ( n - \frac{M}{2} ) {f}_{o} ) - {ε}_{1} cos ( 2 π ( n - \frac{M}{2} ) {f}_{1} ) ) .$$

The referenced interpolation equations in steps d) to h) are included in the computer program description that implements the design method above, where the program being presented in the APPENDIX.

The preferred embodiment of the invention also includes a computer program for the design of a doublet type impulse response of a low-pass filter. The executable source code is written in MATHCAD software syntax and is listed in full detail in the APPENDIX.

### 5.1.3 Low-Pass Filter Design Example and Results

To exemplify the characteristics of the filter and the benefits obtained by the method of this embodiment, the results of a typical design process for a low-pass filter are presented. A typical set of specifications for a low-pass filter are assigned as:
f_{S}=0.290 Hz;
f_{P}=0.335 Hz;
stopband attenuation=60 dB; and
passband peak to peak ripple=0.5 dB.
   The design method of the current embodiment proceeds by setting PBᵢₙ=0.5 dB, SBᵢₙ=60 dB, f_{P}=0.290 Hz and f_{S}=0.335 Hz. Although it is not necessary to follow the details of the design parameters to apply the method, since these are automatically generated and applied in the computer program, they are presented here for the purpose of illustration. These are calculated as SB=55.22 dB, Δ=0.057 Hz, PB_{K}=0.015 dB, PB=0.487 dB, and μ=0.5044. In addition, the values of the parameters entering directly into calculation of the impulse response are M=58, β=5.127, f_{c}=0.3065 Hz , εₒ=0.00603, ε₁=0.003041, f₁=0.2896 Hz, and f₂=0.2726 Hz.

It is instructive to undertake a comparison of the exemplified filter of the preferred embodiment designed above in with filters designed by the two conventional methods referred to in this disclosure, being the Parks-McClellan equiripple and the windowing methods. To achieve this, the two other filter types are designed by their well-known prior art techniques using the same set of specifications listed in [0082].

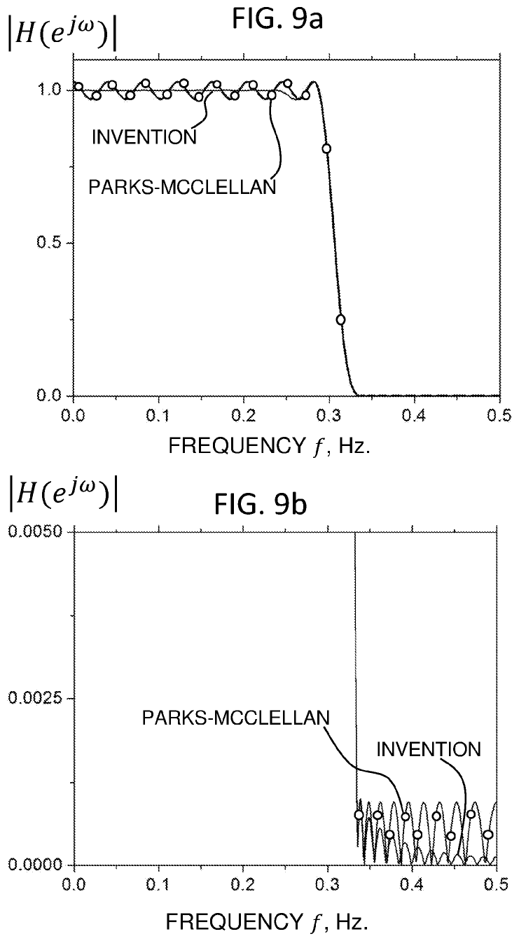

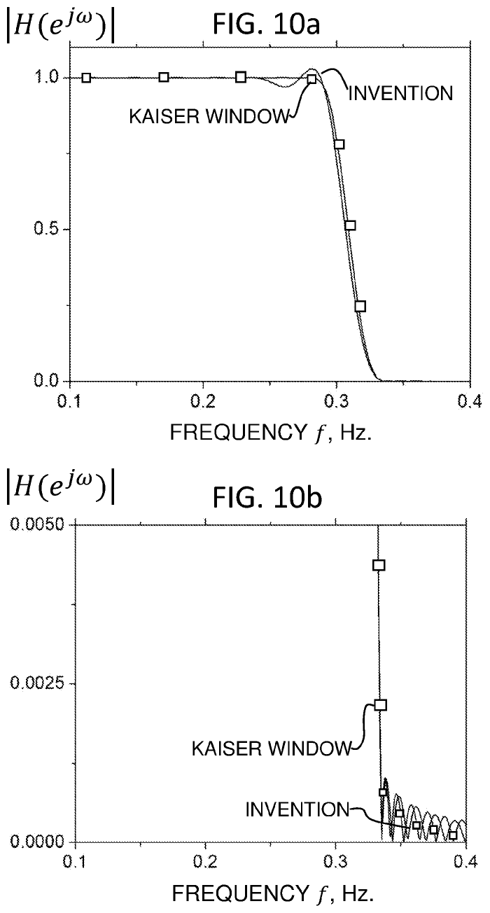

FIG. 9a and FIG. 9b show the linear-scale magnitude responses of the embodiment filter described in [0082] and an equiripple Parks-McClellanfilter designed to have the same specifications, both being plotted on the same graph. The advantage of the preferred embodiment of the invention filter is immediately obvious in the absence of the passband ripple artefact-except for a single symmetrical ripple cycle at the passband edge. The graph shows both magnitude responses to have the same passband peak to peak ripple, the same upper frequency fₚ, and almost identical transition band slopes. FIG. 10b is an expanded view of the stopband region showing both filters having the same stopband attenuation, and the same stopband lower frequency fₛ. Another visible advantage of the filter of the preferred embodiment of the invention is the larger attenuation in the deep stopband compared to the equiripple filter. The equiripple filter requires 51 taps to implement, whereas the preferred embodiment filter requires 59 taps.

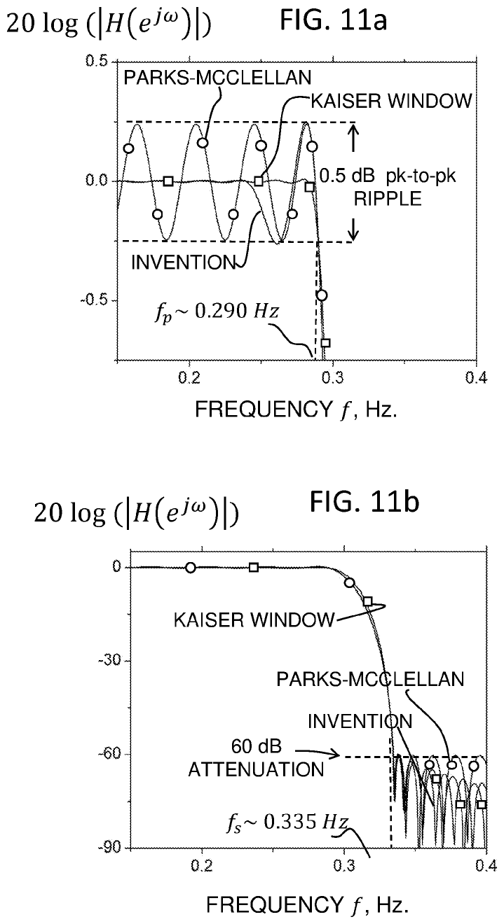

FIG. 10a and FIG. 10b show the linear-scale magnitude response of the embodiment filter described in [0082] and an uncompensated Kaiser window filter designed to have the same specifications, both being plotted on the same graph. The window filter shows characteristic flatness in the passband. The two filters show the same passband upper frequency fₚ, and the same stopband lower frequency fₛ. However, the Kaiser window filter exhibits a larger deviation in the transition band, contributing to about 12% more error signal power being transmitted through the filter. FIG. 11b is an expanded view of the stopband region showing both filters having the same stopband attenuation, and similar deep stopband attenuation behaviour. The Kaiser window filter requires 72 taps, whereas the invention embodiment filter requires 59 taps. In order to reduce the transition band signal energy to the same level as the embodiment filter, the Kaiser window taps would have to be increased to 84.

FIG. 11a and FIG. 11b show the dB-scale passband region of the magnitude responses of all three mentioned filters plotted on the same graphs. The characteristics described for each filter type are clearly visible in the graphs. The filters have the same passband tolerance, and a well-defined fₚ where all three responses converge. The plot also shows the clear onset of deviation in the transition band slope of the Kaiser windowing response that results in the mentioned transition band error. FIG. 11b expands the responses of the three filters in the stopband region, where all three responses converge again at frequency fₛ, thus confirming all three designs to have the same transition bandwidth. The graph also confirms that the three filters have the same stopband attenuation.

The table herein provides a comparative summary of the numerical properties of the three filters of figures FIG. 9a,b to FIG. 11a,b:

| | Parks- | Kaiser | |
|---|---|---|---|
| Property | McClellan | Window | Invention |
| passband upper frequency fₚ (Hz) | 0.2900 | 0.2900 | 0.2900 |
| stopband lower frequency fₛ(Hz) | 0.3350 | 0.3346 | 0.3346 |
| stopband attenuation (dB) | 60.49 | 59.95 | 59.97 |
| passband pk-pk ripple (dB) | 0.472 | 0.502 | 0.502 |
| transition bandwidth (Hz) | 0.0450 | 0.0446 | 0.0446 |
| M (for common trans. bandwidth) | 50 | 71 | 58 |
| M (for common trans. signal error) | 50 | 83 | 58 |

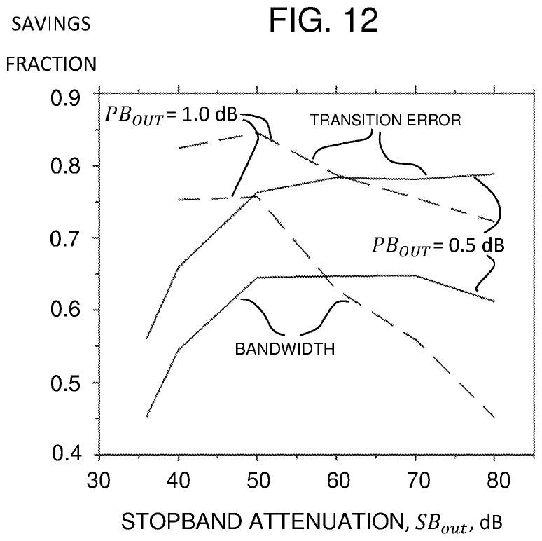

In order to make a meaningful comparison between the filter tap requirements of the various filters, a reference should be made to the minimum number of taps N_{PM} needed by the optimal Parks-McClellan equiripple filter that satisfy the specification requirements. We define the savings fraction as

$$savings fraction ≡ \frac{{N}_{K W} - {N}_{I N V}}{{N}_{K W} - {N}_{P M}} ,$$

where N_{KW} is the number of taps required by the uncompensated Kaiser window filter, and N_{INV} is the number required by the invention filter embodiment. The larger the savings fraction, the more filter taps that are saved. It was found that the savings depend on the passband ripple and stopband attenuation. FIG. 12 is meant to aid in the decision process for selecting the suitable filter design method as related to the number of taps. In the figure, the abscissa is the stopband attenuation, and the ordinate represents the savings fraction. The dashed lines correspond to peak to peak passband ripple of 1.0 dB, while the solid lines correspond to peak to peak passband ripple passband ripple of 0.5 dB. The lower two lines indicated with “BANDWIDTH” correspond to Kaiser window filters designed to have the same bandwidth as the invention, whereas the upper two lines indicated with “TRANSITION ERROR” correspond to Kaiser window filters designed to have the same transition band error signal power.

### 5.1.3 Other Applications

The terms and descriptions used herein are set forth by way of illustration only and are not meant as limitations. Examples and limitations disclosed herein are intended to be not limiting in any manner, and modifications may be made without departing from the spirit of the present disclosure. Those skilled in the art will recognize that many variations are possible within the spirit and scope of the disclosure, and their equivalents, in which all terms are to be understood in their broadest possible sense unless otherwise indicated. In the following paragraphs, we set several examples of alternative embodiments.

The method of the invention is not limited to using only the Kaiser window but can be applied to any conventional window function. Embodiments were successfully developed for several conventional window functions, wherein the optimal discrete prolate spheroidal sequence (DPSS) window showed the best filter tap efficiency for the same set of specifications. However, the absence of an analytic closed form expression for the DPSS window complicates the design process and makes its utilization more demanding computationally.

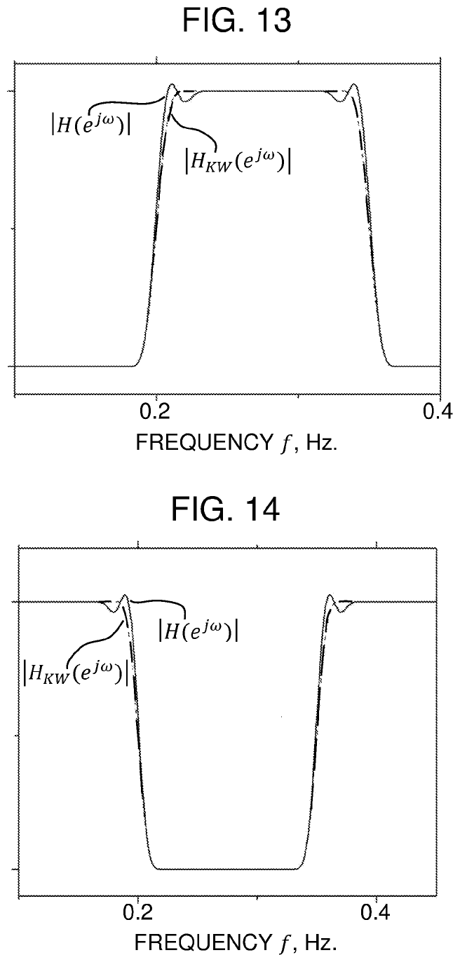

The design method of the preferred embodiment is not limited to the linear phase low-pass filter type only. Indeed, the method of this embodiment can be thought of a design process for the transition band itself between the bands of a filter, and thus being generalizable to other filter types. By changing the positions and amplitudes of the compensating pulses, it is straightforward for those skilled in the art to adapt the method for designing other filter types. Demonstrations of a band-pass filter and a band-stop filter are shown in FIG.13 and FIG. 14, respectively. In each plot, the magnitude response of the invention filter |H(e^{jω})| is plotted alongside that the corresponding uncompensated Kaiser windowing |H_{KW}(e^{jω})| having the same order M.

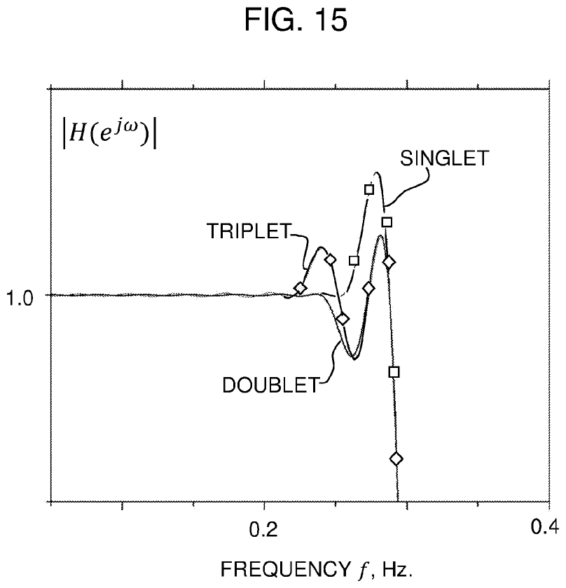

As disclosed in the invention disclosure, the auxiliary pulses are not limited to the doublet scheme of the preferred embodiments, other quantities and sequences of compensating pulses are possible. FIG. 15 shows the passband magnitude responses of the singlet (single compensation pulse) and triplet (three compensation pulses) embodiments of a low-pass filter, along with the fully disclosed doublet embodiment for comparison.

### APPENDIX

The appendix lists a computer program code in PTC Mathcad syntax. The program implements the design procedure of the preferred embodiment disclosed in [0089], wherein the corresponding steps are listed in the comments. The program determines the FIR filter coefficients of a linear phase low-pass filter having target specifications. The complete program code comprises of:

//comment - step (a) entering the low pass filter target specifications:
Pass_Band_Upper_Frequency = 0.290
Stop_Band_Lower_Frequency = 0.335
Pass_Band_Peak_to_Peak_Ripple = 0.5
Stop_Band_Attenuation = 60
//comment - step (b) assigning program variables:
SB_in = Stop_Band_Attenuatic
fp_in = Pass_Band_Upper_Frequenc
fs_in = Stop_Band_Lower_Frequenc:
$PB\_in = \frac{Pass\_Band \_Peak \_to \_Peak \_Rippl}{2}$
Δ_in = fs_in- fp_ir
$fc = \frac{fp\_in + fs\_in}{2}$
//comment - step (c) estimating SB and PB:
$SB = SB\_in δ = {10}^{\frac{- S B}{20}} δ\_dB = 20 \cdot log ( 1 + δ ) PB = PB\_in - δ\_dB$
//comment - step (d) mapping the target stop band attenuation to the simulation
interpolation equations of FIG. 4 and resetting SB and PB:
$SB\_L = \vert \begin{matrix}35 if 35 \leq SB < 40 \\ 40 if 40 \leq SB < 50 \\ 50 if 50 \leq SB < 60 \\ 60 if 60 \leq SB < 70 \\ 70 if 70 \leq SB < 80 \\ 80 if 80 \leq SB < 90\end{matrix} SB\_H = \vert \begin{matrix}40 if 35 \leq SB < 40 \\ 50 if 40 \leq SB < 50 \\ 60 if 50 \leq SB < 60 \\ 70 if 60 \leq SB < 70 \\ 80 if 70 \leq SB < 80 \\ 90 if 80 \leq SB < 90\end{matrix}$
$SBF\_L = \vert \begin{matrix}1.00001 + 0.1416 \cdot PB + - 0.28081 \cdot {PB}^{2} + 0.89854 \cdot {PB}^{3} + - 1.95755 \cdot {PB}^{4} + 1.71355 \cdot {PB}^{5} if 35 \leq SB < 40 \\ 1.00007 + 0.19183 \cdot PB + - 0.48182 \cdot {PB}^{2} + 1.75631 \cdot {PB}^{3} + - 3.31723 \cdot {PB}^{4} + 2.44214 \cdot {PB}^{5} if 40 \leq SB < 50 \\ 1.00194 + 0.31029 \cdot PB + 2.06735 \cdot {PB}^{2} + - 19.31103 \cdot {PB}^{3} + 66.45816 \cdot {PB}^{4} + - 73.49113 \cdot {PB}^{5} if 50 \leq SB < 60 \\ 1.00389 + 0.48347 \cdot PB + 4.33844 \cdot {PB}^{2} + - 39.43556 \cdot {PB}^{3} + 98.35123 \cdot {PB}^{4} + - 80.74569 \cdot {PB}^{5} if 60 \leq SB < 70 \\ 1.007 + 0.58746 \cdot PB + 0.03228 \cdot {PB}^{2} + 2.76098 \cdot {PB}^{3} + - 27.66465 \cdot {PB}^{4} + 37.26344 \cdot {PB}^{5} if 70 \leq SB < 80 \\ 1.00961 + 1.23535 \cdot PB + - 6.37689 \cdot {PB}^{2} + 6.51669 \cdot {PB}^{3} + 14.00084 \cdot {PB}^{4} + - 23.83482 \cdot {PB}^{5} if 80 \leq SB < 90\end{matrix}$
$SBF\_H = \vert \begin{matrix}1.00007 + 0.19183 \cdot PB + - 0.48182 \cdot {PB}^{2} + 1.75631 \cdot {PB}^{3} + - 3.31723 \cdot {PB}^{4} + 2.44214 \cdot {PB}^{5} if 35 \leq SB < 40 \\ 1.00194 + 0.31029 \cdot PB + 2.06735 \cdot {PB}^{2} + - 19.31103 \cdot {PB}^{3} + 66.45816 \cdot {PB}^{4} + - 73.49113 \cdot {PB}^{5} if 40 \leq SB < 50 \\ 1.00389 + 0.48347 \cdot PB + 4.33844 \cdot {PB}^{2} + - 39.43556 \cdot {PB}^{3} + 98.35123 \cdot {PB}^{4} + - 80.74569 \cdot {PB}^{5} if 50 \leq SB < 60 \\ 1.007 + 0.58746 \cdot PB + 0.03228 \cdot {PB}^{2} + 2.76098 \cdot {PB}^{3} + - 27.66465 \cdot {PB}^{4} + 37.26344 \cdot {PB}^{5} if 60 \leq SB < 70 \\ 1.00961 + 1.23535 \cdot PB + - 6.37689 \cdot {PB}^{2} + 6.51669 \cdot {PB}^{3} + 14.00084 \cdot {PB}^{4} + - 23.83482 \cdot {PB}^{5} if 70 \leq SB < 80 \\ 1.00878 + 0.61038 \cdot PB + - 3.0698 \cdot {PB}^{2} + 4.12111 \cdot {PB}^{3} + - 1.80768 \cdot {PB}^{4} + 0.12358 \cdot {PB}^{5} if 80 \leq SB < 90\end{matrix}$
$SBF = \frac{SB\_H - SB\_in}{SB\_H - SB\_L} \cdot SBF\_L + \frac{SB\_in - SB\_L}{SB\_H - SB\_L} \cdot SBF\_H$
$SB = \frac{SB\_in}{SBF} δ = 1 {0}^{\frac{- S B}{20}} δ\_dB = 20 \cdot log ( 1 + δ ) PB = PB\_in - δ\_dB$
//comment - step (e) mapping the target transition bandwidth to the simulation
interpolation equations of FIG. 5:
A_Δ_0 = 0.86082 + −0.00535 · SB + 3.37939 · 10⁻⁵ · SB²
A_Δ_1 = 0.01658 + 0.0014 · SB + −2.40482 · 10⁻⁶ · SB²
t_Δ_1 = −0.02628 + 0.00214 · SB + −2.21286 · 10⁻⁵ · SB²
A_Δ_2 = −0.02601 + 0.0105 · SB + −9.70412 · 10⁻⁵ · SB²
t_Δ_2 = −0.07915 + 0.01628.SB + −1.63398 · 10⁻⁴ · SB²
$Δ F\_Calc = A\_Δ \_ 0 + A\_Δ \_ 1 \cdot {e}^{\frac{- PB}{t \_Δ \_ 1}} + A\_Δ \_ 2 \cdot {e}^{\frac{- PB}{t \_Δ \_ 2}}$
$Δ = \frac{Δ\_in}{ΔF\_Calc}$
//comment - step (f) determining the maximum amplitude of first pulse required for a
maximum passband ripple peak of 0.5 dB from the interpolation equation of FIG. 6:
A_m_0 = 0.00213 + −9.05393 · 10⁻⁵ · SB + 1.1535 · 10⁻⁶ · SB²
A_m_1 = −0.1217 +0.00875 · SB + −6.84652 · 10⁻⁵ · SB²
A_m_2 = 0.53688 + −0.0193 · SB + 2.50718 · 10⁻⁴ · SB²
εmax = A_m_0 + A_m_1 · Δ + A_m_2 · Δ²
//comment - step (g) determining the fractional amplitude parameter of the first pulse to
give the desired passband ripple from the interpolation equation of FIG. 7:
A_ε_0 = 0.03377 + −0.00197 · SB + 2.93054 · 10⁻⁵ · SB² + 1.25997 · 10⁻⁸ · SB³
A_ε_1 = 1.92978 + 0.07855 · SB + −0.00137 · SB² + 1.03723 · 10⁻⁵ · SB³
A_ε_2 = 21.09838 + −1.24226 · SB + 0.0185 · SB² + −1.17641 · 10⁻⁴ · SB³
A_ε_3 = −56.1102 + 3.32885 · SB + −0.0531 · SB² + 3.57809 · 10⁻⁴ · SB³
A _ε_4 = 57.13164 + −3.54325 · SB + 0.06103 · SB² + −4.17802 · 10⁻⁴ · SB³
εF = A_ε_0 + A_ε_1 · PB + A_ε_2 · PB² + A_ε_3 · PB³ + A_ε_4 · PB⁴
ε0 = εF · εmax
//comment - step (h) determining the amplitude parameter of the second pulse from the
interpolation equations of FIG. 8:
A_ε1_0 = 2.68198 + −0.08833 · SB + 0.0011 · SB² + −4.59679 · 10⁻⁶ · SB³
A_ε1_1 = −2.12581 + 0.07315 · SB + −4.24556 · 10⁻⁴ · SB²
A_ε1_2 = 3.06815 + −0.08677 · SB + 3.89087 · 10⁻⁴ · SB²
A_ε1_3 = −2.25646 + 0.05294 · SB + −1.77807 · 10⁻⁴ · SB²
μ = A_ε1_0 + A_ε1_1 · PB + A_ε1_2 · PB² + A_ε1_3 · PB³
ε1 = μ · ε0
//comment - step (i) and step (j) determining the required filter order and the frequency
parameters:
$M = ceil ( \frac{S B - 8}{2 \cdot π \cdot 2.285 \cdot Δ} )$
$fc = fc - \frac{( Δ - Δ\_in )}{2}$
$x 1 = \frac{1}{M + 1} x 2 = \frac{2}{M + 1} f 1 = fc - x 1 f 2 = fc - x 2$
ϕ1 = 2 · π · f1 ϕ2 = 2 · π · f2
//comment - step (k) determining the Kaiser bandwidth parameter:
$β = \vert \begin{matrix}0.1102 \cdot ( SB - 8.7 ) if SB > 50 \\ 0.5824 \cdot {( SB - 21 )}^{0.4} + 0.07886 \cdot ( SB - 21 ) if 21 \leq SB \leq 50 \\ 0 if SB < 21\end{matrix}$
//comment - step (I) looping to calculate M + 1 filter coefficients:
s = 0 .. M
$h\_rect {\_window}_{s} = \frac{sin [ 2 \cdot π \cdot fc \cdot ( s - \frac{M}{2} ) ]}{π \cdot ( s - \frac{M}{2} )}$
$h\_rect {\_window}_{\frac{M}{2}} = 2 \cdot fc$
$m\_kaiser {\_mod}_{s} = \frac{I 0 [ β \cdot \sqrt{1 - {[ \frac{\vert s - \frac{M}{2} \vert}{\frac{M}{2}} ]}^{2}} ]}{I 0 ( β )}$
${h\_aux}_{s} = [ ε0 \cdot cos [ ( s - \frac{M}{2} ) \cdot ϕ1 ] - ε 1 \cdot cos [ ( s - \frac{M}{2} ) \cdot ϕ2 ] ]$
$coefficient {s}_{s} = m\_kaiser {\_mod}_{s} \cdot ( h\_rect {\_window}_{s} + {h\_aux}_{s} )$

1. A method for setting the filter coefficients of an FIR digital filter, with the coefficients being equivalent to the impulse response of the filter, the method comprising the steps of:
a) obtaining the ideal impulse response of an idealized model for the desired digital filter;
b) applying a window function to said ideal impulse response, thereby obtaining a windowed finite impulse response;
c) selecting an auxiliary impulse response characterized by having a finite length that is adjustable to match the length of said windowed finite impulse response, the auxiliary impulse response also producing a transfer function having a phase response that is identical to the phase response of the transfer function of the said windowed finite impulse response, the said transfer function of the auxiliary impulse response also having an amplitude response comprising a plurality of pulses, or the sum or difference thereof, wherein said pulses are characterized by having switchable polarities, adjustable amplitudes, adjustable widths, and adjustable frequency-shifts;
d) summing said auxiliary impulse response and windowed impulse response, thereby obtaining a compensated impulse response;
e) applying a discrete time modulation function to the compensated impulse response to obtain the impulse response of the filter, wherein said modulation does not exclude using an identity modulation;
f) setting the mathematical parameters of the impulse response of the filter;
g) setting the filter coefficients of the FIR filter equal to the impulse response of the filter.

2. A method as claimed in claim 1, wherein the impulse response of the FIR filter is obtained by a method comprising of:
a) summing the transfer function of the windowed impulse response and the transfer function of the auxiliary impulse response, thereby obtaining the compensated transfer function;
b) convolving the compensated transfer function with the DTFT of the discrete time modulation function, thereby obtaining the transfer function of the filter;
c) calculating the impulse response of the filter as the IDTFT of the transfer function of the filter.

3. A method as claimed in claim 1, wherein the transfer function of the auxiliary impulse response has an amplitude response comprising a plurality of an individual mathematical functional form of a pulse, the pulse being the frequency shifted DTFT of a window function, with one or more pulses being used for each transition band in the amplitude response of the windowed impulse response.

4. A method as claimed in claim 3, wherein the auxiliary impulse response, upon summing with the windowed impulse response, has the effect of:
a) increasing the magnitude of the slope in the transition bands of the amplitude response of the compensated impulse response;
b) modifying the ripple magnitudes in the frequency bands outside the transition bands of the amplitude response of the compensated impulse response.

5. A method as claimed in claim 4, wherein the transfer function of the auxiliary finite impulse response has one of its zeroes match the frequency of each of the cutoff frequencies in the amplitude response of the windowed impulse response.

6. A method as claimed in claim 4 or claim 5, wherein the method is further limited by employing only impulse responses that are causal and even symmetric.

7. A method for determining the characteristics of a linear-phase FIR digital filter based on the method claimed in claim 6, the method for determining the filter characteristics comprising the steps of:
a) carrying out a plurality of computer numerical simulations to generate transfer functions of the FIR filter by applying the DTFT to the impulse response of the filter;
b) assigning the input parameters to the simulations to be the set of independent parameters of the mathematical formulation of the method in claim 6 that define the impulse response of the filter, wherein these are identified to be: the length of the windowed impulse response, the cutoff frequencies of the windowed impulse response, the frequency shift parameters and the amplitude parameters of the plurality of pulses of the amplitude response of the auxiliary impulse response, and the input parameters of a windowing design method, wherein the said windowing design method is known in the art, an example of which being the Kaiser window design method;
c) producing a plurality of transfer function simulations, wherein the said input parameter values are stepped iteratively, in a discretized selected range that is unique to each parameter, whereby the simulations cover all chosen input parameter combinations,
d) calculating the magnitude response for each of the said plurality of transfer functions;
e) determining the set of the output filter characteristics for each magnitude response, wherein each output filter characteristics set includes the magnitude of the band gain, the peak to peak ripple, and the transition width, in all bands and transition regions of the amplitude response;
f) creating computer data files of the output filter characteristic sets and the input parameters that produce the said output filter characteristic;
g) using the created data files to plot families of multi-variable graphs of the interdependence between the input parameters and output characteristics;
h) performing graphical analysis on the said graphs by applying a mathematical technique of multi-variable curve fitting, whereby generating a plurality of mathematical interpolation formulae that model the mapping of the input parameters to the output characteristics;

8. A method for designing a linear-phase FIR digital filter based on the method claimed in claim 7, wherein the FIR filter has a target set of filter specifications, the method for designing the filter comprising the steps of:
a) assigning the values of the target set of filter specifications to be a set of output characteristics of the filter, wherein these are used in conjunction with the said multi-variable interpolation formulae to calculate the specific set of said input parameters that will produce the target filter characteristics;
d) using the said specific set of input parameters to calculate the impulse response of the filter;

9. A computer program to design an FIR digital filter based on the method claimed in claim 8, wherein the program is written in any computer program language known in the art.

10. A computer program to emulate numerically the filtering action of an FIR digital filter based on the method claimed in claim 8, wherein the program is written in any computer program language known in the art.

11. An FIR digital filter circuit, wherein the filter coefficients are determined by the method claimed in claim 1 or claim 8, the said circuit comprising M cascaded z⁻¹ time delay units, M+1 filter multipliers, M multipliers being connected to input terminals of the corresponding time delay units and the remaining multiplier being connected to an output terminal of the last time delay unit, and an adder connected to output terminals of the M multipliers.
